(19) United States
(12) Patent Application Publication
(10) Pub. No.: US 2006/0262222 A1
(43) Pub. Date: Nov. 23, 2006

(54) Converter and method for converting digital signals received in the form of modulated multiplexed signals

(76) Inventors: Raoul Monnier, Noyal Sur Vilaine (FR); Philippe Leyendecker, Chateaugiron (FR)

Correspondence Address: Joseph S Tripoli;Thomson Licensing Inc, Patent Operations, P O Box 5312, Princeton, NJ, 08543-5312, US

(21) Appl. No.: 10/553,539

(22) PCT Filed: Apr. 16, 2004
(86) PCT No.: PCT/EP04/50536

§ 371 Date: Jul. 27, 2006

(30) Foreign Application Priority Data
Apr. 17, 2003 (FR) 0304801

(51) Int. Cl. H03M 1/12

(52) U.S. Cl. 348/572; 725/68; 725/100

(57) ABSTRACT

The present invention relates to a converter and a procedure for converting digital signals received in modulated and multiplexed form. The converter comprises means for selecting at least one part of the signals by adjustment at at least one determined frequency, means for demodulating these parts, producing at least one demodulated subsignal, means for demultiplexing these subsignals, extracting these portions, means for remultiplexing these extracted portions in at least one remultiplexed flow, and transformation means for modifying these remultiplexed flows in accordance with at least one communication protocol. It also comprises a means for extracting transmission information received from recipient receivers, the transformation means determining the transmission criteria according to transmission information.

The present invention relates to a converter and to a procedure for converting digital signals received in modulated and multiplexed form, particularly satellite signals.

The digital signals received from satellites are generally processed on reception by a low noise block feed, designated by LNB (“Low Noise Block converter” or “Low Noise Blockdown amplifier”) or by LNC (“Low Noise Converter”). This block, located in the focal point of a receiving satellite antenna, is designed to convert the received signals by frequency downconversion and to amplify them, before sending them to other systems. Hence, digital video signals are traditionally sent next to an antenna input of a decoder receiver unit or STB (“Set Top Box”), where they are subject to frequency selection by tuning. Typically, the LNBs convert part of the signals received in Ku band (and potentially, Ka or C band) to L band (950 MHz-2150 MHz).

However, this technique has disadvantages when several digital decoders (STBs) or other television reception systems are used in a house or building supplied by the satellite antenna equipped with this type of LNB. Indeed:
a standard LNB can only convert one of the four Band/Polarization combinations associated with a programme that one wants to receive; if two or more STBs must receive simultaneously transmitted programmes using different combinations, it must then draw upon more sophisticated LNBs, a system of distribution frames/switches, and wiring that rapidly becomes complex when the number of STBs increases;
the signal transmitted by the LNB is located in a frequency band that is not always correctly supported (high attenuation) by the standard TV signal distribution network (cable or terrestrial) present in houses or apartments; hence, one must either provide a different satellite signal distribution network from the cable/terrestrial signal network, or install better quality cables that enable all these signals to pass simultaneously.

The patent U.S. Pat. No. 5.528.633 describes the combination of a radiofrequency band tuner stage, with a quadrature downconverter stage in a single device. This device acts an amplitude modulation tuner for transforming radiofrequencies into a basic band, and is particularly designed to receive radio frequency signals from an LNB and convert them into signals of a required digital format. The description particularly specifies that the digital data signals derived from any of the amplitude modulation formats can be supplied directly to a digital device at the output (col. 7, lines 41-44).

This technique can be used to make adapting signals at the LNB output easier, but does not resolve the difficulties related to the presence of several STBs.

The document WO-01156297 relates to a domestic system for distributing and storing video. It makes possible the simultaneous wireless distribution of satellite and Internet service carrier signals to several television screens in a house.

For this purpose, a master decoder unit or STB (Set Top Box) connected to external antennas equipped with LNBs is designed to emit radio signals to TV receivers. The master STB comprises, upstream to downstream, a radiofrequency (RF) switching unit, TV tuners, demodulators and demultiplexers for MPEG 2 (Moving Picture Experts Group) programme streams or IP (Internet Protocol).

It also comprises a multiplexer for these flows for access to the TV receivers of the house, via local antennas and slave STBs, as well as a converter to a wireless protocol, such as IEEE 802.11 or Hiperlan2 for example. This protocol can be developed specifically for an application, for example by using a MAC (Medium Access Control) protocol to get the best from a particular RF modulation scheme.

A disadvantage of the techniques divulged in this document is that they require specific terminals adapted to the wireless protocol used in a given domestic network and that they are only fully effective with an appropriate RF modulation scheme.

The present invention proposes a converter of satellite digital signals received in modulated and multiplexed form that makes possible a simultaneous recognition of several receivers in a manner that can be reliable and particularly flexible.

The converter of the invention can particularly make it possible to recognize several receivers of different types in a local network, possibly communicating with the converter in several modes of transmission.

More generally, the signal converter of the invention can be used for received digital signals, whether or not they are satellite signals, and particularly applications for cable or terrestrial transmissions.

The converter of the invention can also, in preferred embodiments, resolve the problems of downstream frequency acceptance in a standard TV signal distribution network.

The invention also relates to a procedure for converting received digital signals, having the aforementioned advantages.

By “converter” and “conversion”, the transformation of digital signals of a first form into a second distinct form is herein meant in a wide sense.

For this purpose, the aim of the invention is a converter of digital signals received in modulated and multiplexed form, comprising means for selecting at least one part of these signals by adjustment at at least one determined frequency and for demodulating these parts, capable of producing at least one demodulated subsignal.

The converter also comprises:

means for demultiplexing subsignals, designed to extract portions of these subsignals;

means for remultiplexing the portions extracted from at least one remultiplexed flow;

and means for transforming this remultiplexed flow, designed to modify this remultiplexed flow in compliance with specific criteria for transmission to recipient receivers, these transformation means being provided to modify said remultiplexed flow so as to render it compliant with at least one communication protocol.

According to the invention, the converter comprises a means for extracting transmission information received from recipient receivers, and the transformation means are able to determine the transmission criteria according to this transmission information.

Hence, the converter can be capable of flexibly and automatically adapting the nature of the output signals according to the types of receiving devices or to the network to which they belong.

This dynamic selection of transmission criteria, therefore of the communication protocol(s) used, is particularly surprising to the extent that it departs from existing techniques, relying on predefined criteria set in relation to the type of the network.

The use of transmission information can be limited to certain transmission criteria only, particularly to a predefined set of communication protocols. Hence, either the converter recognises the protocol to use as being part of its capacities and adapts accordingly, or it observes that the required transmission criteria are not part of its capacities and renounces transmitting signals to the receiver(s) concerned.

According to an advantageous embodiment, the transformation means are capable of making the remultiplexed flow compliant with at least two communication protocols associated with the same physical layer, for example Hiperlan2 and IEEE 802.11a. The transmission channels to the different receivers concerned can thus be the same (in the example above: wireless transmission). In that way, the converter can be used for different types of terminals, including simultaneously, without any intervention being required and in an economic manner (the implementation can notably be purely software).

According to another embodiment, the transformation means are capable of making the remultiplexed flow compliant with at least two communication protocols associated with two distinct physical layers, for example Ethernet and IEEE1394. In this case, separate communication channels are provided in the converter for the different protocols respectively concerned.

However, the converter only preferentially produces signals according to a protocol corresponding to a given channel (for example, an IEEE1394 bus) when it detects the presence of receivers associated with this channel, by means of the transmission information. This latter can possibly be reduced to a simple indication of presence of receivers connected downstream of this channel.

The converter of the invention is particularly interesting when it serves a community, for example a company or a building. Indeed, the risks of terminal diversity thus find themselves considerably heightened with respect to a simple domestic network.

The selection and demodulation means are advantageously capable of “adjustment at at least one determined frequency” owing to the presence of one or more tuners. Hence, according to a first embodiment of these means, they comprise a tuner that enables the required frequencies to be selected successively. In a second embodiment, they comprise several tuners in parallel, coupled to a head-end sampling and a digital signal processing to select the channel downstream. This last embodiment can particularly receive several channels located at different frequencies in a given frequency band and extract these channels in parallel.

Several converters can be combined in such a manner as to make available signals from several separate sources to the receivers. To do this, the remultiplexed flows from the different converters, made compatible by similar transmission criteria, are grouped advantageously in a central distribution system. This central system thus acts as a relay with respect to the recipient receivers.

Moreover, the deployment of the systems may be obtained in different ways, particularly:
within an individual house,
within a building,
or within a group of individual houses or buildings.

The protocol used for the remultiplexed flows (or at least one of the protocols used) is advantageously a communication protocol to a digital network. When the converter is incorporated into an LNB, this preferred form means recovering part of the functions being typically found in an STB from this LNB, so as to send a digital signal at the output of this LNB in a standard used for example in the world of the PC.

These embodiments are particularly judicious with respect to new technologies, to which the market is strongly attracted by applications linked to the domain of the personal computer or PC, a convergence between this world and that of television is currently emerging. Hence, a distribution of the TV signal in a form identical to the one used for the transmission of data between PCs can indeed be proposed within a house or building.

Such a mode of distribution also enables types of services other than video (such as specific data or Internet) to be received more easily by satellite. It thus authorises an extension of offers available on Internet terminals (“IP” for “Internet Protocol” terminals) that are now capable of receiving digital TV via ADSL (Asymmetric Digital Subscriber Line) to the satellite packages.

Preferentially, the communication protocol is chosen from among the Ethernet, IEEE1394 (Institute of Electrical and Electronic Engineers), IEEE802.11a, Hiperlan2 standards and a powerline communication protocol.

In fact, at least three variants concerning this protocol can be considered: a first version for which a cable is required to transmit the data; a second “wireless” version; and a third version that uses a mains supply network. For the first, one can particularly draw upon the Ethernet (10, 100 or 1000 base T, for example) standard or on a powerline standard to make up the network. For the second, the standards IEEE802.11a or IEEE802.11e are good candidates. The high level protocol that can be considered is IP (Internet Protocol). Naturally, other similar standards can be used. For example, another solution than IEEE802.11a/IP in the “wireless” version is Hiperlan2/IEEE1394.

In a preferred embodiment relating to upstream communication, the converter is intended to convert the digital signals transmitted by satellite. The converter is thus preferentially integrated into an LNB.

In other embodiments, it is intended to convert the signals transmitted by cable or terrestrially, being able particularly to include an LMDS (“Local Multipoint Distribution System”) or an MMDS (Microwave Multipoint Distribution System), or even digital terrestrial reception in the UHF/VHF bandwidth (for “Ultra-High Frequencies” and “Very High Frequencies”), for example in compliance with the standard DVB-T (“Digital Video Broadcasting—Terrestrial”).

In an advantageous form, the converter is capable of processing two of these signal types.

Advantageously, the selection and demodulation means are provided to select and demodulate transmission digital channels in order to produce the subsignals. These channels are typically selected from among all the channels available on a set of polarisation and band combinations. For satellite signals, a “quattro” type LNB is used advantageously for this purpose, which is designed to supply the four standard polarisation/band combinations (vertical or horizontal polarization, high or low band).

The demultiplexing means are preferentially designed to extract audiovisual programmes, constituting at least some of the portions. The remultiplexing means is therefore advantageously capable of remultiplexing these portions in MPEG (Moving Picture Experts Group) transport streams constituting the remultiplexed flows. The number of transport streams thus created depends on the number of different programmes that are simultaneously watched or recorded. If this number is fairly low (typically below 8), a single multiplex is sufficient. This remultiplexing operation can occur with a modification of the transport packets: it may indeed be advisable to modify for example the value of certain packet identifier (PIDs) fields or the value of certain clock reference fields (“PCRs” for “Program Clock References”).

Moreover, the converter also preferentially comprises a means for extracting extraction information received from recipient receivers, and the transformation means are able to determine the subsignals and the portions according to this extraction information. In this way, the converter can adapt itself to the requests of the receivers and in particular send them the required programmes.

By the expression “from the receivers”, it is meant not only the messages sent directly by these receivers, but also the messages transmitted by one or more entities of a local network to which these receivers are linked.

In some realization variants, the information indicated above (transmission criteria, subsignals and subsignal portions) or some of it, is not obtained from information sent by the recipient receivers, but is either preset or set by an operator independent from the receivers and the local network to which they belong.

According to one particularly advantageous realization, the converter also comprises means for modulating return signals from recipient receivers.

It can therefore, particularly, simplify the feedback of information for a satellite return channel (two-way LNB). A significant advantage of such a realisation is that it authorizes identical recipient receivers (in particular STBs), whether or not a return channel to an operator is provided. Modulation functions usually designed to be integrated in the receivers with return channel to operator are indeed incorporated into the converter. It is sufficient that the receivers are provided with local interactive capabilities, that is have an uplink communication channel to the converter.

In an advantageous embodiment with such a centralised modulation, the converter can modulate the return signals according to at least two distinct types of modulation. Such a multi-function converter is able to adapt to several return transmission channels, for example cable and satellite, according to the application that is made of it.

The invention also relates to a conversion procedure for digital signals received in modulated and multiplexed form, in which adjustment at at least one determined frequency selects at least one part of these signals and these parts are demodulated so as to produce at least one demodulated subsignal,

This conversion procedure comprises the stages of:

demultiplexing the subsignals so as to extract portions of these subsignals,

remultiplexing the extracted portions into at least one remultiplexed flow,

and transformation of this remultiplexed flow in accordance with specific criteria for transmission to recipient receivers, so as to render this remultiplexed flow compliant with at least one communication protocol,

According to the invention, the procedure also comprises a stage for extracting transmission information received from recipient receivers, and the transformation stage comprises a determination of the transmission criteria according to this transmission information.

This conversion procedure is preferentially implemented by means of a converter in accordance with any one of the embodiments of the invention.

The invention also applies to a receiver of multiplexed digital signals in accordance with a communication protocol.

According to the invention, the receiver comprises preparation means and uplink communication channel transmission information means, this transmission information comprising information on at least one communication protocol associated with the receiver.

The receiver of the invention is preferably designed to receive a remultiplexed flow from the converter in accordance with any one of the embodiments of the invention.

The invention will be better understood and illustrated by means of the following embodiments and implementations, by no means limiting, with reference to the figures attached in the appendix, in which:

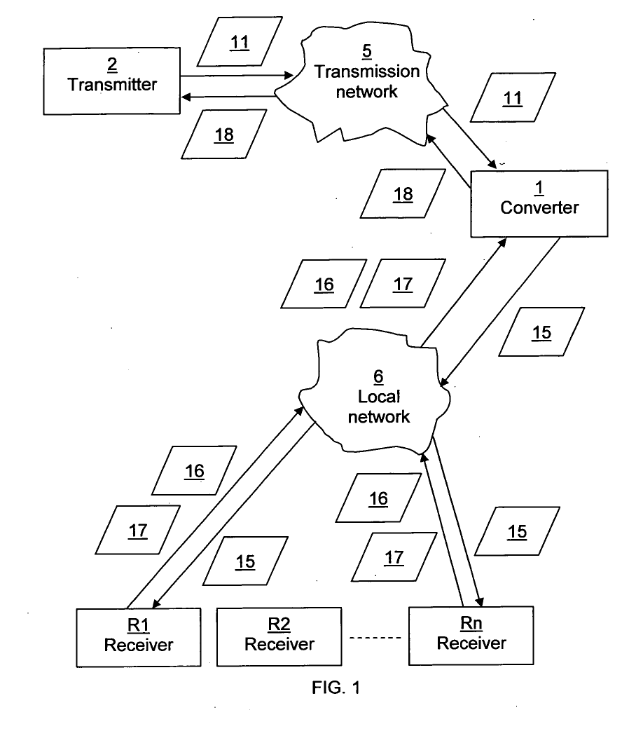

FIG. 1 is a functional diagram of a system for transmitting signals to a transmission network, for transforming the signals received by a converter according to the invention and for transmitting flows from the converter to the receivers of a local network;

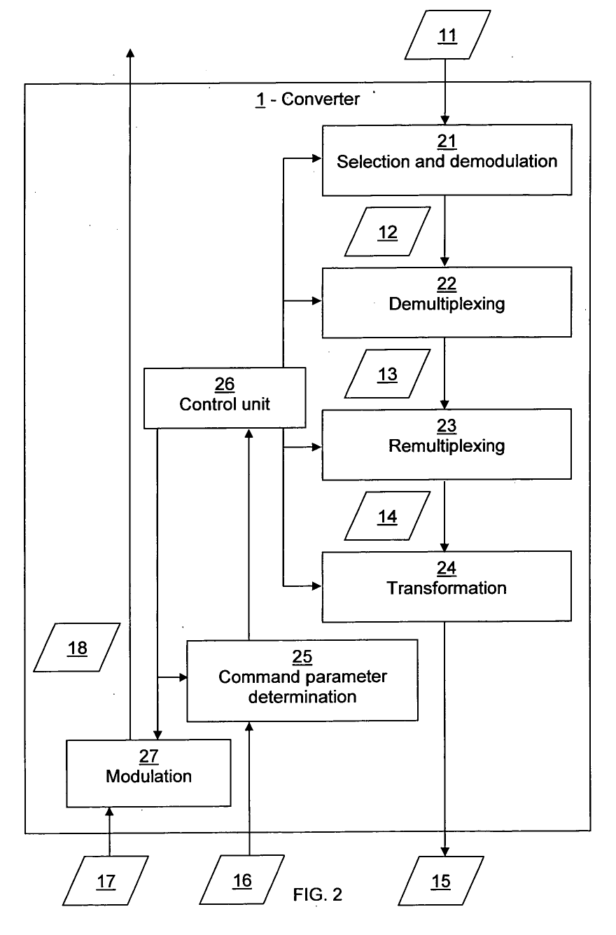

FIG. 2 shows the functional blocks of the converter of FIG. 1 in diagrammatic form;

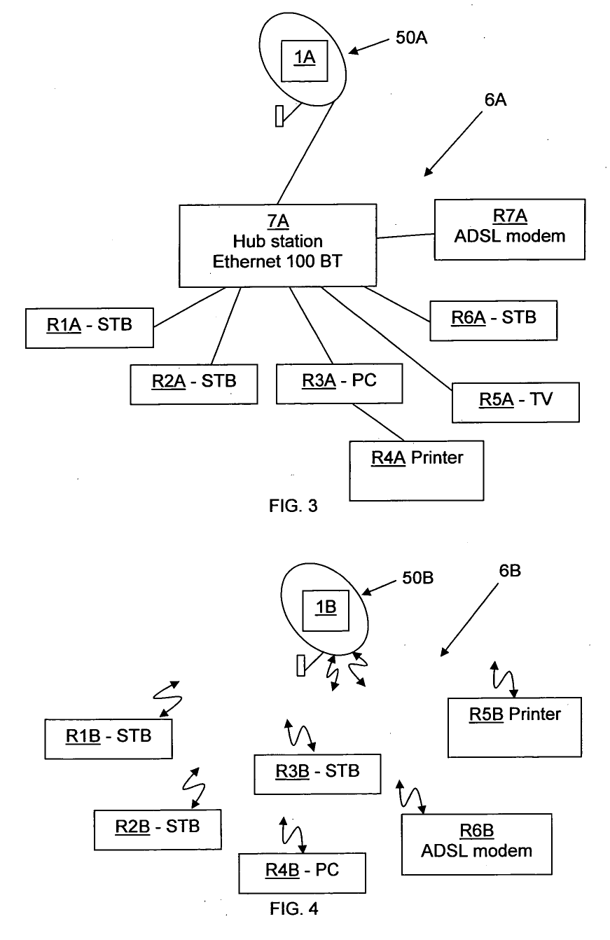

FIG. 3 shows a first application of the converter of FIGS. 1 and 2, with an LNB combined with a cable network;

FIG. 4 shows a second application of the converter of FIGS. 1 and 2, with an LNB combined with a wireless network;

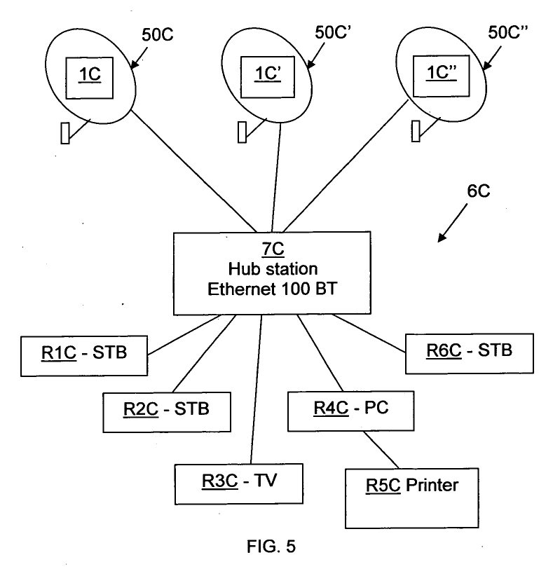

FIG. 5 shows a third application of the converter of FIGS. 1 and 2, with three LNBs combined jointly with a cable network;

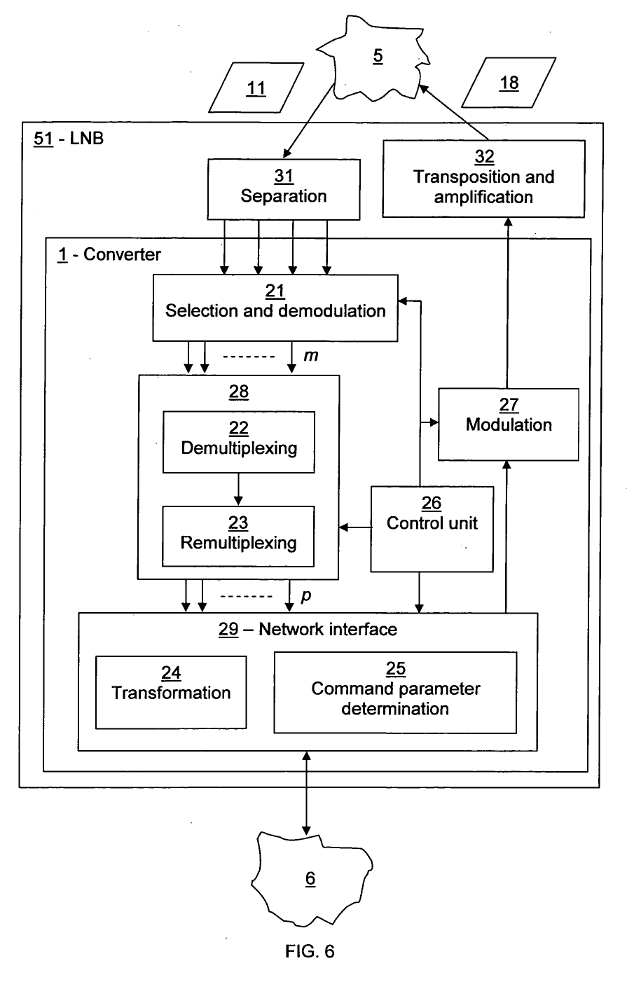

FIG. 6 diagrammatically shows the integration of the converter of FIGS. 1 and 2 in an LNB, for example for one of the embodiments of FIGS. 3 to 5;

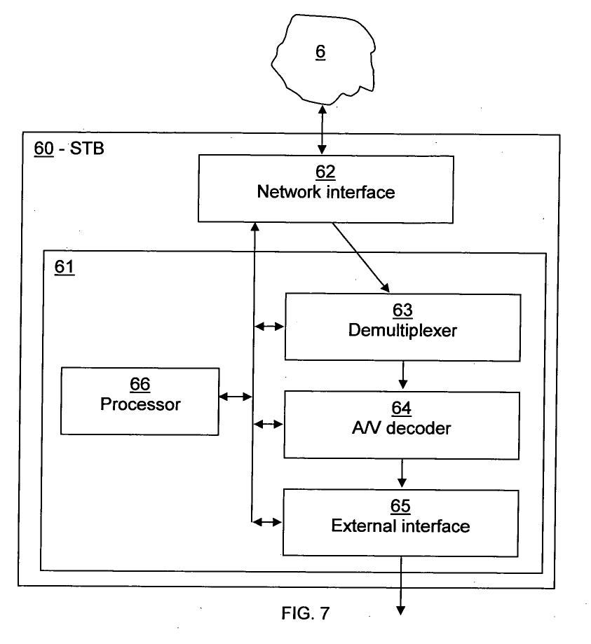

FIG. 7 shows the functional blocks of an STB of one of the receivers of FIGS. 1 to 6;

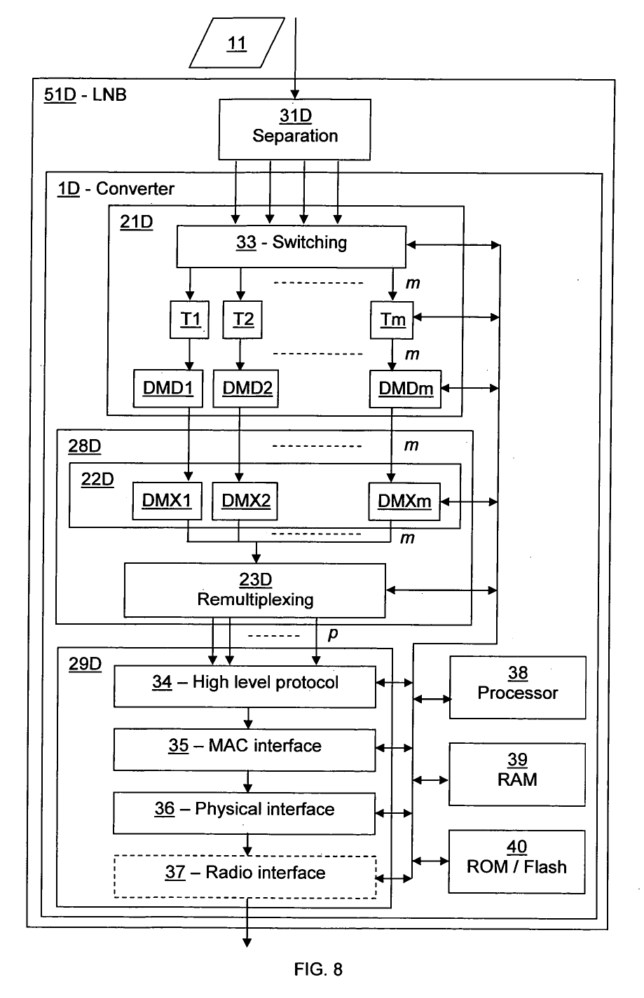

FIG. 8 details one implementation of the LNB of FIG. 6;

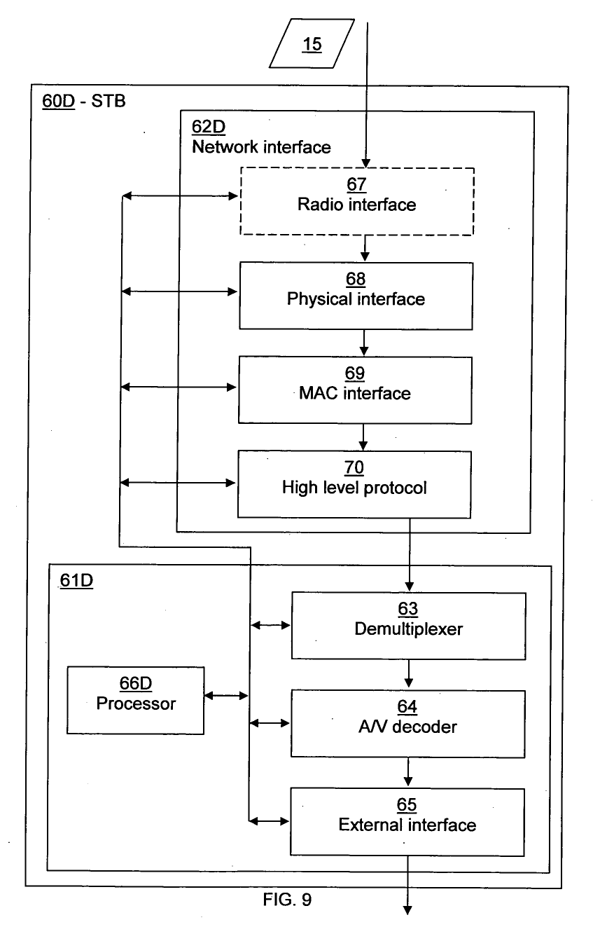

and FIG. 9 details one implementation of the STB of FIG. 7.

In the figures and in the following explanations, the modules shown are functional units that may or may not correspond to physically distinguishable units. For example, these modules or some of them can be grouped together in a single component, or constitute functions of the same software. Contrariwise, some modules can possibly be composed of separate physical entities.

Moreover, identical or similar elements are designated by the same references, to which alphabetic suffixes can be added.

A transmitter 2 (FIG. 1) sends by broadcasting broadcast signals 11 in modulated and multiplexed form to receivers R1, R2 . . . Rn, via a transmission network 5 that is, for example, a satellite or cable network. The broadcast signals 11 are received by a converter 1 of signals associated with a local network 6, linking the receivers R1-Rn. The function of this converter 1 is to transform the signal 11 so as to produce flows 15 adapted to the local network 6 and the receivers R1-Rn, particularly according to control information 16 sent by these receivers or by the entities of the local network 6.

Moreover, in the embodiment shown, the receivers R1-Rn are able to communicate return signals by means of the converter 1 to the transmitter 2—or to another system, such as a services operator. These return signals are sent in the form of uplink communication signals 17 to the converter 1, then converted by the converter 1 into modulated return signals 18, which are then relayed to the transmitter 2.

More precisely (FIG. 2), the converter 1 comprises a tuning selection and demodulation module 21 applied to the received signals 11, designed to produce subsignals 12 for example extracts of determined transmission channels. The converter 1 thus comprises a demultiplexing module 22 able to extract portions 13 of these subsignals 12, consisting typically of audiovisual programmes. The function of a remultiplexing module 23 is to multiplex these portions 13 into one or more remultiplexed flows 14, being able to consist of one or more MPEG transport streams. A transformation module 24 is responsible for modifying these remultiplexed flows 14 in accordance with determined criteria of transmission to the receivers R1-Rn, for example according to a communication protocol adapted to the local network 6. The adapted flows 15 thus produced at the output of the transformation module 24 are sent to the receivers R1-Rn.

The converter 1 also has a command parameter determination module 25, designed to extract control parameters, intended to govern the functions implemented in converter 1, from control information 16 communicated by the local network 6 (particularly the receivers R1-Rn): protocol to implement with regard to the local network 6, types of subsignals and portions to extract, etc.

Furthermore, a modulation module 27 in the converter 1 processes the uplink communication signals 17, in order to produce the modulated return signals 18.

Moreover, a control unit 26 supervises the operation of all the modules of the converter 1.

Particular embodiments and implementations will now be described in more detail, in the case of satellite transmissions satellite, the converter 1 being integrated into an LNB.

In a first application (with the reference “A”, FIG. 3), a satellite antenna 50A featuring an LNB with converter 1A is connected to a local cable network 6A based on the standard Ethernet 100 Base T (hereafter “100BT” to simplify) and having a hub station 7A (“100BT hub”). This station serves various receiver devices R1A, R2A . . . R7A such as STBs, television screen, PC, printer and ADSL modem. The converter 1A of the LNB, cabled to the hub station 7A, is capable of transforming the satellite signals 11 received by producing the adapted flows 15 directly according to the Ethernet 100BT standard.

In a second application (with the reference “B”, FIG. 4), another satellite antenna 50B featuring an LNB with converter 1B is provided to transmit to a local wireless network 6B being based on the standard IEEE802.11a. This station supplies various receiver devices R1B, R2B . . . R7B such as STBs, PC, printer and ADSL modem. The converter 1B of the LNB can convert the received satellite signals 11 by producing the adapted flows 15 directly according to the standard IEEE802.11a.

In a third application (with the reference “C′”, FIG. 5), three satellite antennas 50C, 50C′ and 50C″ respectively featuring LNBs with converters 1C, 1C′ and 1C″, are connected to a local cable network 6C being based on the standard Ethernet 100BT and having a hub station 7C. This station serves various receiver devices R1C, R2C . . . R6C such as STBs, television screen, PC and printer. Each of the converters 1C, 1C′ and 1C″, wired to the hub station 7C, is capable of transforming the satellite signals 11 received by producing the adapted flows 15 directly according to the Ethernet 100BT standard. The recognition of several antennas thus enables multiple packages to be supported for the network 6C. Moreover, the realization described authorizes a simplification of the installation by eliminating the accessories of signal broadcasting and switching required in a standard installation.

The realisation of an LNB and an STB adapted to the converter 1 is developed hereafter. An LNB 51 containing the converter 1 (FIG. 6) comprises in addition to the converter 1, a separation module 31 of combinations of the received signals 11. This separation module 31 can provide, for example, the four polarisation/band combinations, the LNB being of the type Quattro, and transmit to the selection and demodulation module 21. It is also designed to downconvert the frequency and amplify the received signals.

Within the converter 1, the selection and demodulation module 21 is constituted by a multi-channel tuner/demodulator, that can select and demodulate m satellite digital channels determined from among all the channels available on the four polarisation/band combinations. Moreover, a demultiplexing and remultiplexing unit 28 that contains the demultiplexing 22 and demultiplexing 23 modules, extracts from the m demodulated channels the programmes that the viewer(s) want to watch or record, and remultiplexes these channels, for example into p MPEG transport streams (the “multiplex”).

A network interface 29 of the converter 1, incorporating the transformation 24 and command parameter determination 25 modules, is responsible for encapsulating these p multiplex in the transmission frames of the communication protocol (for example IP and Ethernet 100BT or IEEE802.11a). This network interface 29 also extracts from control information 16 received from the different devices present on the network 6, information that is necessary for determining the requesting devices, together with the channels and programmes that must be demodulated. This information is used to fill in the recipient fields of the transmission frames and to control the tuner/demodulator 21 and the multiplexer/demultiplexer (unit 28) by means of the control unit 26 via a control bus. The network interface 29 also has the additional function of recovering the data to be transmitted (uplink communication signals 17) and transmitting them to the modulation module 27.

The LNB 51 also comprises a transposition and amplification module 32, designed to process the modulated return signals 18 transmitted by the modulation module 27, before being returned by satellite.

An appropriate STB 60 (FIG. 7) corresponding to the LNB 51 comprises a network interface 62 intended to receive the adapted flows 15 from the converter 1, that is complying with a communication protocol on local network (e.g. Ethernet 100BT or IEEE802.11a). The STB 60 also comprises a set 61 of standard function including a demultiplexer module 63, an audio/video decoder 64, an external interface 65 to the television screen and a processor 66 controlling these different entities via a control bus. The STB 60 is therefore identical to a standard satellite STB with the exception of its satellite reception head-end part (tuner and demodulator), replaced here by the network interface 62 enabling the data present on the network used to be received.

According to particular embodiments of the STB 60, the interface 62 and the processor 66 are adapted to transmit to the LNB 51 presence information, hence possibly data relating to the identity of the communication protocol used.

Hence, in a first example, the STB 60 sends this information at the request of the converter 1 (this request notably being able to be triggered by an operator during an initialisation or update phase, or be triggered periodically in an automatic manner).

In a second example, the STB 60 is designed to trigger the sending of this information at each connection to a network, and to send an end of presence signal at each disconnection.

In some realization variants, no satellite return channel is designed, such that the LNB does not comprise the modules 27 and 32.

Specific implementation modes are described hereafter for the LNB 51 and STB 60 (suffix “D”). To simplify the presentation, the parts of the LNB 51D and STB 60D relating to the satellite return channel are not represented or developed in the comments.

The LNB 51D (FIG. 8) comprises the separation module 31D supplying the four polarisation/band combinations (LNB Quattro), in the form of four IF signals (Intermediate Frequencies) in the frequency band 950 MHz-2150 MHz.

The selection and demodulation module 21 (with the reference 21D) comprises a switching matrix 33, that can orient any of the four signals to a set of m tuners T1, T2 . . . Tm and demodulators respectively associated DMD1, DMD2 . . . DMDm. The tuners Ti are known tuners, providing an analogue signal that is then sampled and converted into a digital signal by the first stages of the DMDi demodulators. In an embodiment variant, these isolated m tuners Ti are replaced by a digital tuner that samples the IF signals very early on and digitally carries out all the filtering and transposition operations to supply the m signals to demodulate.

The demultiplexing and remultiplexing unit 28 (with the reference 28D) receives the m demodulated subsignals from the demodulators DMD1-DMDm respectively in m demultiplexers DMX1, DMX2 . . . DMXm (that form the demultiplexing unit 22D). The demodulation and demultiplexing m operations are the ones commonly found in satellite STBs. The function of the m demodulators DMDi and demultiplexers DMXi is to process the signals according to the transmission standard used (e.g. DVB-S in Europe—for “Digital Video Broadcasting—Satellite” and DSS in the USA—for “Digital Satellite System”) and to recover the data corresponding to the programmes that the viewers connected to the local network 6 want to watch or record.

In the demultiplexing and remultiplexing unit 28D, the remultiplexing unit 23D can remultiplex the programmes m restored in flows p (e.g. transport streams for the MPEG standard), that may be constituted by a single flow, and present them at the network interface 29D.

This network interface 29D comprises successively in the transmission system:

a management device 34 of a high level protocol, such as IP for example;

an interface 35 for access control to the support, call the MAC (Medium Access Control) interface, responsible for managing the access to the transmission support; this interface, which depends on the support, is different for the cable version and the wireless version;

a physical interface 36, designed to physically process the signals present on the transmission support and whose nature depends on this support;

and optionally for a wireless link (e.g. with the IEEE802.11a protocol), a radio interface 37 responsible for the operations associated with radio emissions (transposition, filtering, power control, gain control, etc.).

A processor 38 equipped with its RAM memory (Random Access Memory) referenced 39 and its ROM memory (Read Only Memory) or flash, referenced 40, controls all the functions of the LNB 51D, and performs the software parts of these functions.

The STB described, referenced 60D (FIG. 9), differs from standard satellite STBs through its network interface 62D, which replaced the satellite reception head-end part (tuner and demodulator). This network interface 62D comprises successively in the transmission system:

optionally, if the local network 6 is of the wireless type, a radio interface 67;

a physical interface 68, physically processing the signals present on the interface; this interface 68 depends on the transmission support used and is different for the cable version and the wireless version;

a MAC interface 69, providing an access layer to the transmission support; this interface 69 also depends on the transmission support;

and a high level protocol layer 70, for example IP.

According to the embodiment variants, the converter 1 is included:

in an LNB to receive terrestrial signals, and no longer satellite signals;

or in a cable reception centre.

According to other embodiment modalities than those described above, the converter is dissociated from the receiving station of the broadcast signals, for example the LNB. The converter is then preferably arranged in a device located downstream of a frequency downconverter and signal amplification device (such as an LNB) and upstream of recipient receivers. It can thus be incorporated particularly into an STB.

1. Converter of digital signals received in modulated and multiplexed form, comprising means for selecting at least one part of the said signals by adjustment at at least one determined frequency and means for demodulating the said parts, capable of producing at least one demodulated subsignal
the said converter also comprising:
means for demultiplexing the said subsignals designed to extract portions of the said subsignals;
means for remultiplexing the said portions extracted from at least one remultiplexed flow;
means for transforming said remultiplexed flow, designed to modify said remultiplexed flow in compliance with specific criteria for transmission to recipient receivers, said transformation means being provided to modify said remultiplexed flow so as to make it comply with at least one communication protocol, and
means for extracting transmission information received from the recipient receivers,
transformation means being capable of determining the transmission criteria according to said transmission information;
wherein said transmission information of a recipient receiver depends on the type of recipient receiver or on the network type to which it belongs.

2. Converter according to claim 1, wherein the transformation means are able to return said remultiplexed flow in accordance with at least two communication protocols associated with the same physical layer.

3. Converter according to claims 1, wherein at least one of said communication protocols is a protocol for communication to a digital network, preferentially chosen from among the standards Ethernet, IEEE1394, IEEE802.11a and Hiperlan2.

4. Converter according to claim 1, intended to convert digital signals transmitted by satellite.

5. Converter according to claim 1, wherein the selection and demodulation means are designed to select and demodulate transmission digital channels in order to produce said subsignals.

6. Converter according to claim 1, wherein the demultiplexing means are designed to extract audiovisual programmes constituting at least some of the said portions.

7. Converter according to claim 6, wherein the remultiplexing means are capable of remultiplexing said portions into MPEG transport streams constituting said remultiplexed flows.

8. Converter according to claim 1, wherein it also comprises means for extracting extraction information received from recipient receivers, and in that the transformation means are capable of determining said subsignals and said portions according to said extraction information.

9. Converter according to claim 1, wherein it also comprises means for modulating feedback signals from recipient receiver.

10. Conversion procedure for digital signals received in modulated and multiplexed form, in which adjustment at at least one determined frequency selects at least one part of said signals and said parts are demodulated so as to produce at least one demodulated subsignal,
said procedure comprising the following stages:
demultiplexing of said subsignals, so as to extract portions of said subsignals,
remultiplexing the said portions extracted from at least one remultiplexed flow (14),
transformation of said remultiplexed flow in accordance with specific criteria for transmission to recipient receivers, so as to render the remultiplexed flow compliant with at least one communication protocol,
extraction of transmission information received from said recipient receivers,
the transformation stage comprising a determination of transmission criteria according to this transmission information,
wherein said transmission information of a recipient receiver depends on the type of recipient receiver or on the network type to which it belongs.
said conversion procedure being preferentially implemented by means of a converter in accordance with claim 1.

11. Receiver of multiplexed digital signals compliant with a communication protocol,
wherein said receiver comprises means for the preparation and transmission via uplink communication of transmission information, said transmission information comprising information on at least one communication protocol associated with the said receiver, said transmission information depending on the type of receiver or network to which it belongs
said receiver being preferentially designed to receive a remultiplexed flow from a converter according to claim 1.
